(19) United States
(12) Patent Application Publication
(10) Pub. No.: US 2011/0309216 A1
(43) Pub. Date: Dec. 22, 2011

(54) Mounting system that securely couples a monitor

(76) Inventor: Sung I. Oh, West Covina, CA (US)

(21) Appl. No.: 13/134,931

(22) Filed: Jun. 20, 2011

Related U.S. Application Data
(60) Provisional application No. 61/356,613, filed on Jun. 20, 2010.

(51) Int. Cl. H05K 7/00

(52) U.S. Cl. 248/201

(57) ABSTRACT

A mounting system includes a shaft having a longitudinal axis, the shaft has a first cross-sectional portion and a second cross-sectional portion, the first cross-sectional portion being a semi-circular configuration, and the second cross-sectional portion being a substantially flat. A wall bracket has a first opening adapted to receive the shaft to allow the shaft to rotate about its longitudinal axis. A mounting bracket has a hook and a base, the base having a substantially planar surface adapted to couple to the rear side of the monitor. The hook is adapted to receive the shaft when the substantially flat portion of the shaft is substantially parallel with the base of the first mounting bracket and allow the shaft to rotate within the hook, and when the shaft is rotated relative to the hook, the shaft is locked within the hook.

### RELATED APPLICATION

This application claims priority to a provisional application Ser. No. 61/356,613, filed Jun. 20, 2010, which is hereby incorporated by reference.

### FIELD OF THE INVENTION

This invention is directed to a mounting system adapted to couple a monitor to a supporting surface.

### BACKGROUND OF THE INVENTION

Flat panel monitors such as computer monitors, LCD, plasma, slim televisions, and the like (collectively referred to as “monitor(s)”) are becoming popular because they can be mounted onto a wall to save floor space and for their aesthetically pleasing appearance. In particular, monitors are generally mounted to a wall with a mechanical support arm or a bracket, and then fixed in a desired orientation to maximize the viewing angle of the monitor.

The traditional mounting systems typically provide one or two panel mounting brackets and a wallplate. The wallplate generally has an upper lip and a bottom lip. The panel mounting brackets generally has a hook on the top and a latching mechanism on the bottom. During the installation process, the wallplate is attached to a wall, and the panel mounting brackets are attached to the rear side of the monitor. The monitor is then lifted and anchored to the wallplate by placing the top hook of the panel mounting bracket over the upper lip of the wallplate and securing the latching mechanism of the panel mounting bracket to the bottom lip of the wallplate. During the installation process, however, the user needs to tilt the monitor up in order to connect the video and audio cables to the jacks on the rear side of the monitor. One of the problems with titling the monitor up is that the top hook is not secured to the wallplate so that the monitor may disengage with the top lip of the wallplate and fall. As such, there is a need for a mounting system that secures a monitor when the monitor is tilted up.

### INVENTION SUMMARY

A mounting system may be adapted to couple a monitor to a supporting surface. The mounting system includes a shaft having a longitudinal axis, the shaft having a first cross-sectional portion and a second cross-sectional portion, the first cross-sectional portion being a semi-circular configuration, and the second cross-sectional portion being a substantially flat; a first wall bracket adapted to couple to a supporting surface, the first wall bracket having a first opening adapted to receive the shaft to allow the shaft to rotate about its longitudinal axis; and a first mounting bracket having a hook and a base, the base having a substantially planar surface adapted to couple to the rear side of the monitor, the hook adapted to receive the shaft when the substantially flat portion of the shaft is substantially parallel with the base of the first mounting bracket and allow the shaft to rotate within the hook, and when the shaft is rotated relative to the hook, the shaft is locked within the hook.

Other systems, methods, features, and advantages of the invention will be, or will become, apparent to one with skill in the art upon examination of the following figures and detailed description. It is intended that all such additional systems, methods, features, and advantages be included within this description, be within the scope of the invention, and be protected by the following claims.

### BRIEF DESCRIPTION OF THE DRAWINGS

The invention can be better understood with reference to the following drawings and description. The components in the figures are not necessarily to scale, emphasis instead being placed upon illustrating the principles of the invention. Moreover, in the figures, like referenced numerals designate corresponding parts throughout the different views.

FIG. 1 shows a perspective view of a mounting system.

FIG. 2 shows a front view of the mounting system.

FIG. 3 shows a side view of the mounting system.

FIG. 4 shows a close up view of a mounting bracket and a shaft in an unlocked position.

FIG. 5 shows a close up view of a mounting bracket and a shaft in a locked position.

FIG. 6 shows a perspective view of another mounting system.

FIG. 7 shows a perspective view of a shaft.

FIG. 8 shows a side view of a wall bracket.

FIG. 9 shows a side view of a mounting bracket with a hook.

FIG. 10 shows a side view of the mounting system of FIG. 6.

### DETAIL DESCRIPTION OF THE INVENTION

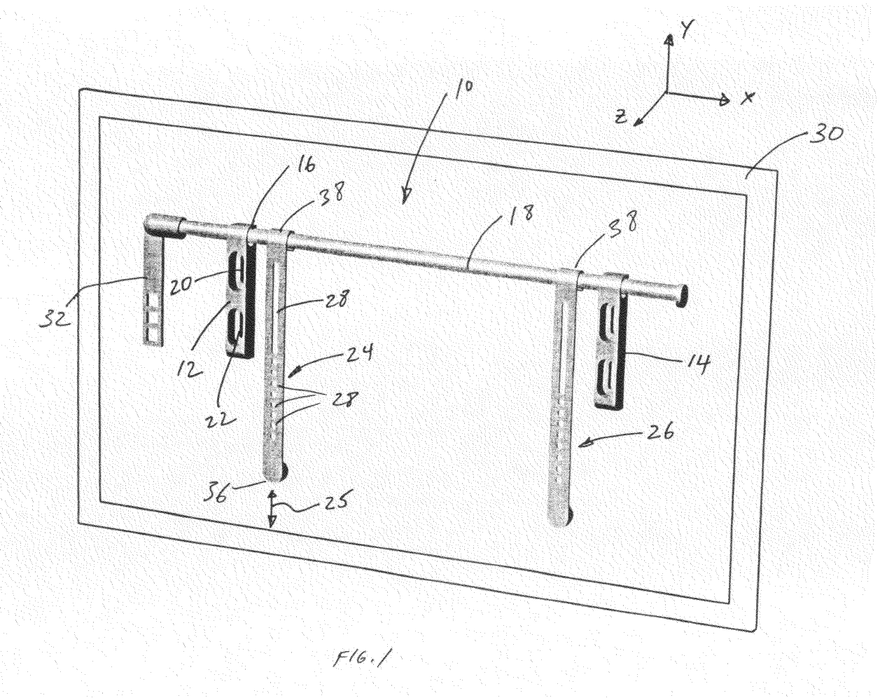

FIG. 1 shows a perspective view of a mounting system 10 in reference to X, Y, and Z axes. The mounting system 10 may include a first bracket 12 and a second bracket 14. The two brackets 12 and 14 may be similar. As such, the first bracket 12 will be described in detail, which will be applicable to the second bracket 14. The first bracket 12 may have a first opening 16 adapted to receive a shaft 18. The bracket 12 may also have a second opening 20 and a third opening 22. The second opening 20 may be elongated. The second and third openings 20 and 22 may be adapted to receive a screw so that the bracket 12 may be coupled to a supporting surface such as a wall.

The mounting system 10 may include a first panel mounting bracket 24 and a second panel mounting bracket 26. The two brackets 24 and 26 may be similar. As such, the first panel mounting bracket 24 will be described in detail, which will be applicable to the second panel mounting bracket 26. The bracket 24 has a longitudinal axis 25, and a plurality of holes 28 may be provide along the longitudinal axis. One or more screws may be used to attach the bracket 24 to the threaded holes provided on the rear side of the monitor 30. A handle 32 may be provided to rotate the shaft 18.

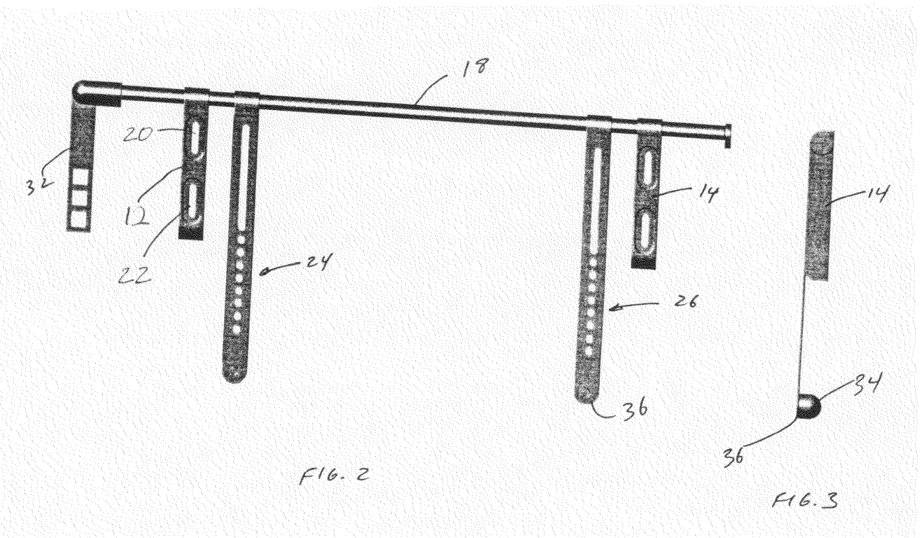

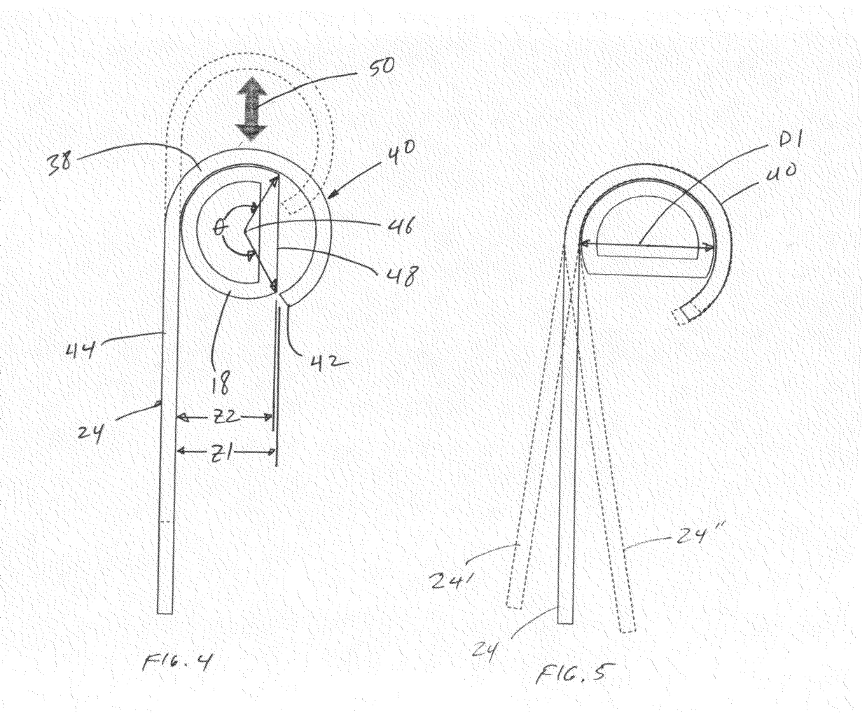

FIG. 2 shows a front view of the mounting system showing the second and third openings on the first bracket 12. FIG. 3 shows a side view of the mounting system. A spacer 34 may be provided on the first end 36 of the panel mounting bracket 26 to hold the TV in the upright position.

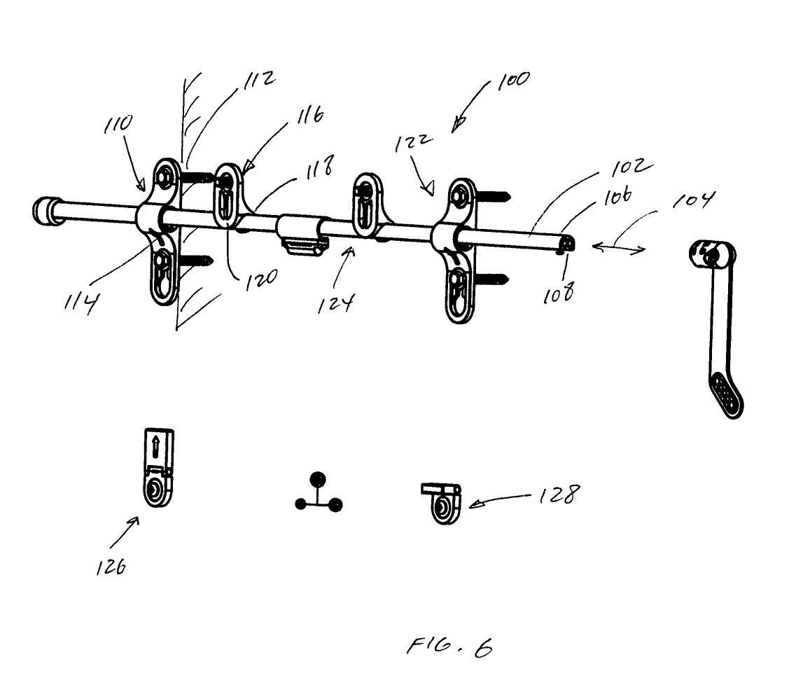

FIG. 4 shows a close up view of a second end 38 of the panel mounting bracket 24. The second end 38 may have a semi circular hook 40 with a tip 42. The distance between the tip 42 and the base 44 of the panel mounting bracket may be Z1. The shaft 18 may have a semi-circular configuration with the focal point 46 and where the angle θ may be greater than 180°, and a substantially flat portion 48. FIG. 4 shows the shaft 18 in an open position where the distance between the flat portion 48 and the base 44 is Z2. The distance Z1 may be greater than the distance Z2. When the shaft 18 is in the open position relative to the hook 40, this allows the shaft 18 to slide in and out of the hook 40 as indicated in the direction arrow 50. As such, the TV can be hung onto a wall much like hanging a picture frame.

FIG. 5 shows the shaft 18 rotated into a locked position. The diameter D1 of the shaft 18 may be greater than the distance Z1. As such, once the shaft is rotated into the locked position using the handle 32, the shaft 18 and the hook 40 are engaged so that the TV does not fall off the wall. With the semi-circular portion of the shaft 18 engaged with the hook 40, the TV may be tilted up as illustrated by the dotted line 24′ or tilted down as illustrated by the dotted line 24″ without the hook disengaging from the shaft 18.

FIG. 6 shows a mounting system 100 adapted to couple a monitor to a supporting surface such as a wall. The mounting system may include a shaft 102 having a longitudinal axis 104. The shaft 102 may have a first cross-sectional portion 106 and a second cross-sectional portion 108. The first cross-sectional portion 106 may have a semi-circular configuration, and the second cross-sectional portion 108 may have a substantially flat surface. A first wall bracket 110 may be adapted to couple to a supporting surface 112 such as a wall. The first wall bracket 110 may have a first opening 114 adapted to receive the shaft 102 to allow the shaft to rotate about its longitudinal axis 104.

The mounting system 100 may include a first mounting bracket 116 having a hook 118 and a base 120. The base 120 may have a substantially planar surface adapted to couple to the rear side of the monitor. The hook 118 may be adapted to receive the shaft 102 when the substantially flat portion 108 of the shaft 102 is substantially parallel with the base 120 and allow the shaft 102 to rotate within the cavity of the hook 118. When the shaft 102 is rotated relative to the hook 118, the shaft 102 may be locked within the hook 118 as described above in reference to the hook 40.

The mounting system 100 may include a second wall bracket 122 and a second mounting bracket 124 which are similar to the first wall bracket 110 and the first mounting bracket 116, respectively. The mounting system 100 may also include a first kick stand 126 and a second kick stand 128 to push the bottom portion of the monitor away from the wall so that the monitor may be in a upright position.

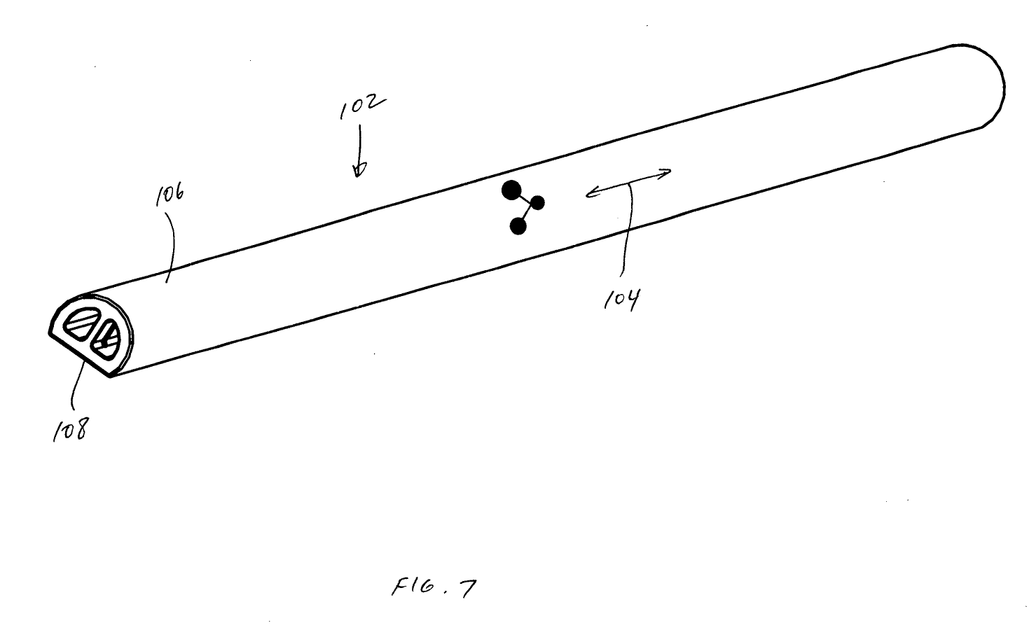

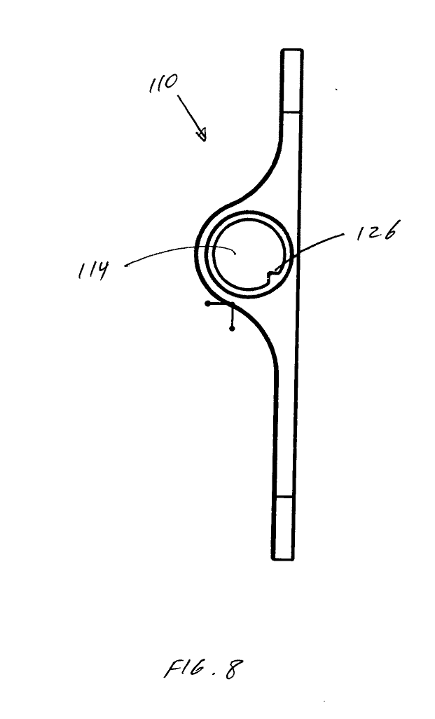

FIG. 7 shows a perspective view of the shaft 102 having a first cross-sectional portion 106 and a second cross-sectional portion 108. The first cross-sectional portion 106 may have a semi-circular configuration, and the second cross-sectional portion 108 may have a substantially flat surface.

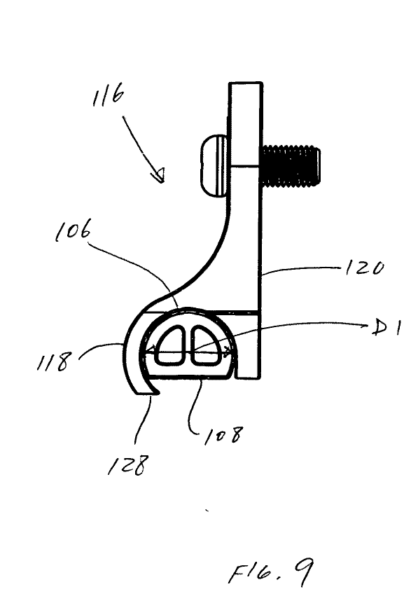

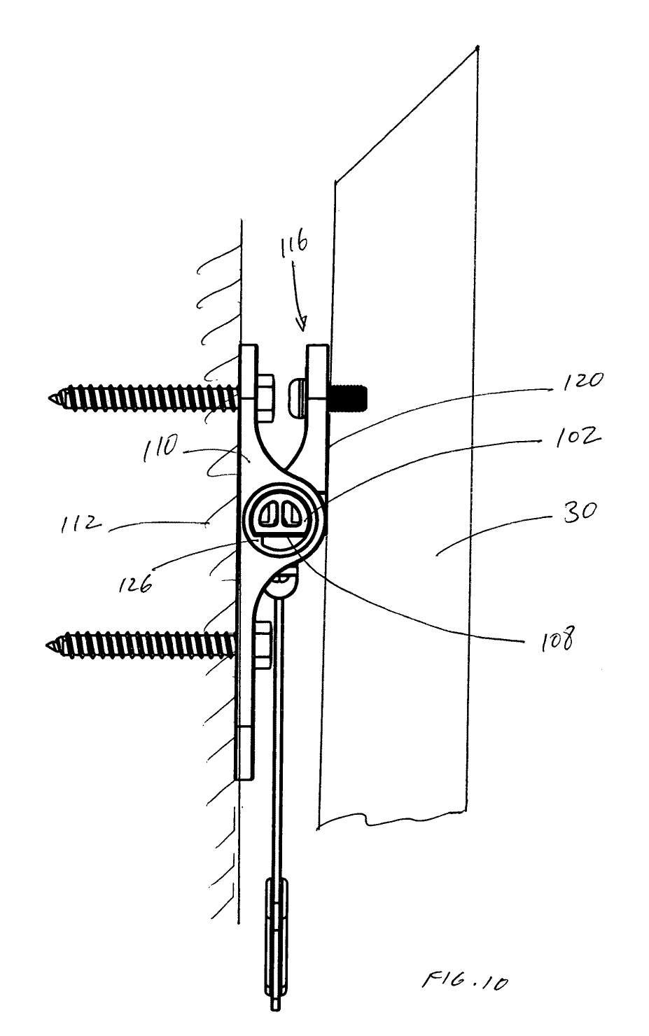

FIG. 8 shows a side view of the first wall bracket 110 having a first opening 114 adapted to receive the shaft 102 to allow the shaft to rotate about its longitudinal axis 104. The opening 114 may have a notch 126 to stop the shaft from rotating 360°. FIG. 9 shows a side view of the first mounting bracket 116 with the hook 118 and the base 120. The hook 118 may be adapted to receive the shaft 102 and when the substantially flat portion 108 of the shaft 102 is rotated relative the mounting bracket 116 so that the flat portion 108 of the shaft is no longer parallel with the base 120, the shaft 102 may be locked within the hook 118. In other words, when the shaft if rotated, the distance between the tip end 128 and base 120 is smaller than the diameter D1 of the shaft 102 so that the shaft is locked within the hook 118.

FIG. 10 shows a side view of the first wall bracket 110 anchored to a supporting surface 112, and the base 120 of the mounting bracket 116 coupled to a monitor 30. The notch 126 in the first wall bracket 110 stops the shaft 102 when it is being rotated when the shaft 102 is in a fully locked position as shown in FIG. 10. Conversely, when the shaft is rotated in a clockwise direction to, the notch 126 stops the shaft 102 when the flat portion 108 of the shaft is substantially parallel with the base 120 of the mounting bracket 116.

While various embodiments of the invention have been described, it will be apparent to those of ordinary skill in the art that many more embodiments and implementations are possible within the scope of this invention. For instance, in reference to FIG. 1, additional actuators may be added to the base based plate 1304 to support heavier monitors if necessary. Accordingly, the invention is not to be restricted except in light of the attached claims and their equivalents.

What is claimed is:

1. A mounting system adapted to couple a monitor to a supporting surface, the monitor having a rear side, the mounting system including:
a shaft having a longitudinal axis, the shaft having a first cross-sectional portion and a second cross-sectional portion, the first cross-sectional portion being a semi-circular configuration, and the second cross-sectional portion being a substantially flat;
a first wall bracket adapted to couple to a supporting surface, the first wall bracket having a first opening adapted to receive the shaft to allow the shaft to rotate about its longitudinal axis; and
a first mounting bracket having a hook and a base, the base having a substantially planar surface adapted to couple to the rear side of the monitor, the hook adapted to receive the shaft when the substantially flat portion of the shaft is substantially parallel with the base of the first mounting bracket and allow the shaft to rotate within the hook, and when the shaft is rotated relative to the hook, the shaft is locked within the hook.

2. The mounting system according to claim 1, including:
a second wall bracket adapted to couple to a supporting surface, the second wall bracket having a first opening adapted to receive the shaft to allow the shaft to rotate about its longitudinal axis; and
a second mounting bracket having a hook and a base, the base having a substantially planar surface adapted to couple to the rear side of the monitor, the hook adapted to receive the shaft when the substantially flat portion of the shaft is substantially parallel with the base of the second mounting bracket and allow the shaft to rotate within the hook, and when the shaft is rotated relative to the hook, the shaft is locked within the hook.

3. The mounting system according to claim 1, where the hook has a tip end, the hook having a semi-circular cavity relative to a focal point between the base and the tip end, and the hook having a gap between the tip end and the base, and when the substantially flat portion of the shaft is substantially parallel with the base, the shaft is able to pass through the gap between the tip end and the base.

4. The mounting system according to claim 1, where the first mounting bracket has a longitudinal axis, and the first mounting bracket has a plurality of holes along the longitudinal axis.
